(19) United States
(12) Patent Application Publication
(10) Pub. No.: US 2007/0292806 A1
(43) Pub. Date: Dec. 20, 2007

(54) Dynamic Puddle Developing Process

(76) Inventor: Chung-Jung Hsu, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/423,956

(22) Filed: Jun. 14, 2006

(51) Int. Cl. G03F 7/26

(52) U.S. Cl. 430/311; 430/331

(57) ABSTRACT

A dynamic puddle developing process is disclosed. First, a semiconductor substrate having a photoresist disposed thereon is provided, in which the photoresist has been exposed. Next, a developer is disposed on the surface of the photoresist and a first static puddle process is performed to maintain the semiconductor substrate in a static status within a first time interval. A rotating puddle process is performed thereafter to generate a first rotating speed for the semiconductor substrate, and a second static puddle process is performed to maintain the semiconductor substrate in a static status within a second time interval. Next, a rinsing process is performed to rinse the semiconductor substrate and remove the developer from the surface of the photoresist.

### BACKGROUND OF THE INVENTION

1. Field of the Invention

The present invention relates to a developing process, and more particularly, to a dynamic puddle developing process.

2. Description of the Prior Art

As the development of electronic products such as digital cameras and scanners increases, the demand for image sensors in the consumer market also increases accordingly. Two of the most common image sensors utilized in the market today include charged coupled device, CCD sensors, and CMOS image sensors. CMOS image sensors have been widely utilized in the semiconductor industry today because of advantages, such as: low operating voltage, low power consumption, high efficiency, and easy random access.

Please refer to FIG. 1. FIG. 1 is a perspective diagram illustrating a conventional CMOS image sensor according to Taiwan Patent No. 442892. As shown in FIG. 1, the fabrication of a CMOS image sensor first involves disposing a plurality of photodiodes 4, utilized for collecting lights, onto a semiconductor substrate 2. Next, a deposition process and at least an interconnective wiring process are performed to form a plurality of conductive structures 6 and a passivation layer 8 composed of silicon nitride or silicon oxide on each of the photodiodes 4. Next, a planarization layer 10, composed of photoresist material, is formed on the passivation layer 8 for reducing the impact caused by height difference of the passivation layer 8. Next, processes including photoresist coating, exposure, and curing are performed to define a plurality of color filters 12 on the surface of the planarization layer 10. Preferably, the color filters 12 include red, green, and blue color filters corresponding to each of the photodiodes 4. Subsequently, a barrier rib 14 and a plurality of microlenses 16 are formed on each of the color filters 12. The microlenses 16 are able to effectively collect and focus light from the external environment, and project the light onto each of the photodiodes 4 through the barrier rib 14, the color filters 12, the planarization layer 10, and the passivation layer 8.

In general, the photoresist material used for fabricating color filters 12 are divided into two types: dye type photoresist and pigment type photoresist. The pigment type photoresist utilized by industries today are negative photoresist materials, in which the photoresist is composed of approximately 25% pigment, with polymer substrate, additives, and solvents comprising the remainder of the composition. In contrast to other photoresist materials utilized in integrated circuit fabrications, the pigment type photoresists becomes even more difficult to dissolve after the exposure and development processes. Hence, a much greater quantity of solvents must be added during the fabrication process to completely dissolve the photoresist material. Pigment type photoresist materials commonly used today include: SR-3100L, SG-3300L, SB-3300, and RGB-3000L.

Please refer to FIG. 2. FIG. 2 is a perspective diagram illustrating the relationship between the transmittance and wavelength of the pigment type photoresist SR-3100L, SG-3300L, and SB-3300L. As shown in FIG. 2, the pigment type photoresist SR-3100L, SG-3300L, and SB-3300L includes red photoresists 22, 24, and 26 of SR-3100L, green photoresists 32, 34, and 36 of SG-3300L, and blue photoresists 42, 44, and 46 of SB-3300L. The thickness of the red photoresist 22 is 0.7 μm, the thickness of the red photoresist 24 is 1.1 μm, and the thickness of the red photoresist 26 is 1.5 μm. Similarly, each of the green photoresists 32, 34, 36 and the blue photoresists 42, 44, 46 also include a thickness of 0.7 μm, 1.1 μm, and 1.5 μm respectively. In order to reduce the focal path of the end device, finding photoresists with reduced thickness while maintaining a satisfactory spectral response has become critically important.

Hence, another pigment type photoresist material, RGB-3000L, is commonly utilized today for providing a much better spectral response. Please refer to FIG. 3. FIG. 3 is a perspective diagram illustrating the relationship between the transmittance and wavelength of the pigment type photoresist RGB-3000L. As shown in FIG. 3, the photoresist RGB-3000L includes red photoresists 52, 54, and 56 of SR-3000L, green photoresists 62, 64, and 66 of SG-3000L, and blue photoresists 72, 74, and 76 of SB-3000L. Similar to the photoresists SR-3100L, SG-3300L, and SB-3300, the red photoresists 52, 54, 56, the green photoresists 62, 64, 66, and the blue photoresists 72, 74, 76 include three different thicknesses: 0.7 μm, 0.9 μm, and 1.1 μm respectively. It should be noted that the photoresists of RGB-3000L, while at a much smaller thickness, are able to provide a much better spectral response. Nevertheless, as the thickness of the red photoressits 52, 54, and 56 of SR-3000L decreases, the pigment concentration of the photoresists also increases significantly. As shown in FIG. 2 and FIG. 3, the red photoresists 52, 54, and 56 of SR-3000L includes a pigment concentration of 35%, whereas the red photoresists 22, 24, and 26 of SR-3100L only includes a pigment concentration of 25%.

Hence, in order to improve the spectral response of the photoresists, the conventional method of fabricating a CMOS image sensor utilizes a red photoresist material SR-3000L with a significantly higher pigment concentration to increase the color resolution of the CMOS image sensor. However, after performing the after development inspection (ADI), red pigment particles are often revealed on the product wafer due to the red photoresist SR-3000L coated on a wafer, thereby decreasing the quality and yield of the CMOS images sensor produced. In order to remove the red pigment particles, industries today utilize developers containing a much stronger base for conducting developing processes. Nevertheless, this method causes peeling problems and damages the wafer.

### SUMMARY OF THE INVENTION

It is therefore an objective of the present invention to provide a dynamic puddle developing process for reducing the pigmentation phenomenon caused by the conventional method of fabricating a CMOS image sensor.

According to the present invention, a dynamic puddle developing process includes the following steps: (a) providing a semiconductor substrate having an exposed photoresist disposed thereon; (b) coating a developer on the surface of the photoresist; (c) performing a first static puddle process to maintain the semiconductor substrate in a static status within a first time interval; (d) performing a rotating puddle process to generate a first rotating speed for the semiconductor substrate; (e) performing a second static puddle process to retain the semiconductor substrate in a static status within a second time interval; and (f) performing a rinsing process to rinse the semiconductor substrate and remove the developer from the surface of the photoresist.

According to another embodiment of the present invention, a dynamic puddle developing process includes the following steps: (a) providing a semiconductor substrate having an exposed photoresist disposed thereon; (b) coating a developer on the surface of the photoresist; (c) performing a first static puddle process to maintain the semiconductor substrate in a static status within a first time interval; (d) performing a vibrating process to vibrate the semiconductor substrate; (e) performing a second static puddle process to maintain the semiconductor substrate in a static status within a second time interval; and (f) performing a rinsing process to rinse the semiconductor substrate and remove the developer from the surface of the photoresist.

Preferably, the present invention first disposes an exposed photoresist on a wafer, coats a developer on the surface of the photoresist, performs a dynamic puddle process, such as a low speed rotating process or a vibrating process on the wafer, and stops the rotating wafer for approximately ten seconds. In other words, by utilizing a dynamic puddle developing process that involves performing a rotating puddle process and a static puddle process on the wafer, the present invention is able to improve the red pigmentation problem caused by the high pigment concentration of the red photoresist material SR-3000L while fabricating a CMOS image sensor, thereby improving the overall yield of the product.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective diagram illustrating a conventional CMOS image sensor according to Taiwan Patent No. 442892.

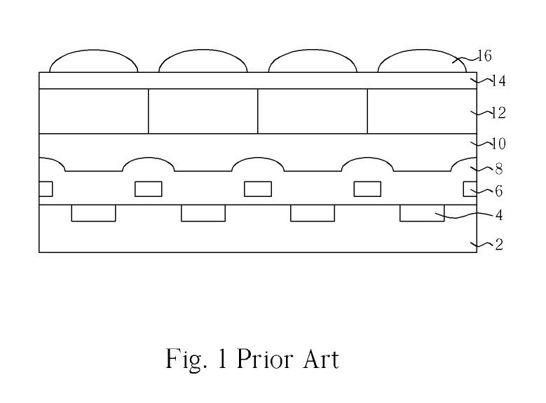

FIG. 2 is a perspective diagram illustrating the relationship between the transmittance and wavelength of the pigment type photoresist SR-3100L, SG-3300L, and SB-3300L.

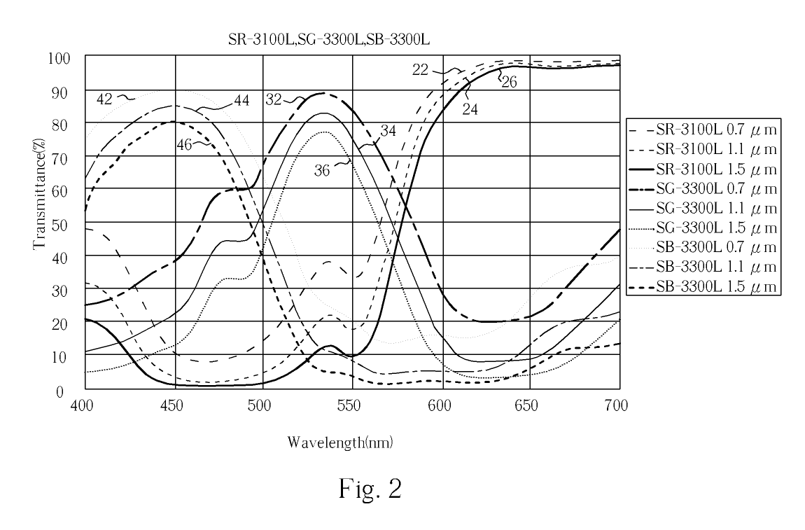

FIG. 3 is a perspective diagram illustrating the relationship between the transmittance and wavelength of the pigment type photoresist RGB-3000L.

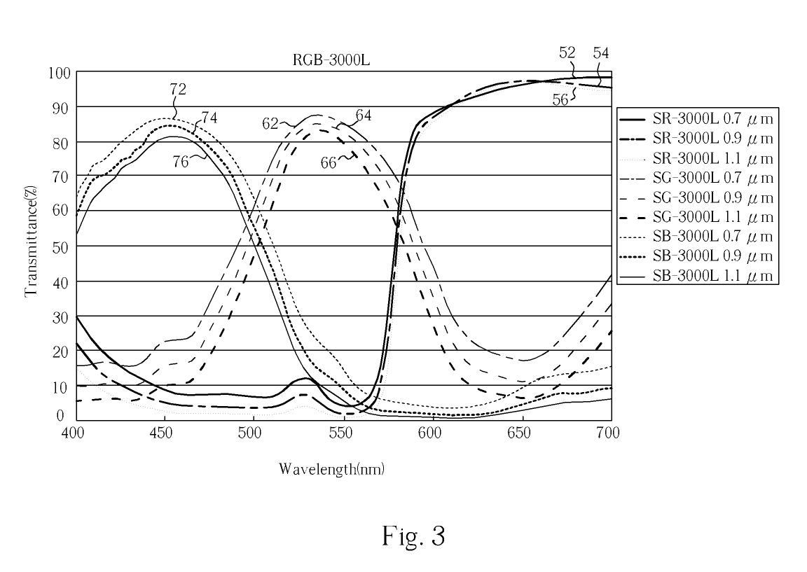

FIG. 4 is a flow chart diagram showing the process of fabricating a CMOS image sensor according to the preferred embodiment of the present invention.

FIG. 5 is a flow chart diagram showing the process of fabricating a CMOS image sensor according to another embodiment of the present invention.

### DETAILED DESCRIPTION

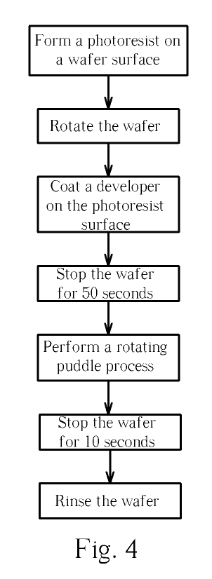

Please refer to FIG. 4. FIG. 4 is a flow chart diagram showing the process of fabricating a CMOS image sensor according to the preferred embodiment of the present invention. As shown in FIG. 4, a semiconductor substrate is first provided, in which the semiconductor substrate is a silicon wafer, a silicon on insulator substrate, or a composite substrate composed of silicon, germanium, silicon germanium, or silicon carbide. Next, a spin-coating process is performed to form a photoresist on the surface of the semiconductor substrate, in which the photoresist is fabricated into a color filter in the later process. Preferably, the photoresist is selected from a pigment type photoresist commonly utilized in conventional fabrication processes, such as an RGB-3000L pigment type photoresist. Additionally, the surface of the wafer may include standard CMOS image sensor devices and relative circuit structures, such as a plurality of photodiodes utilized for collecting light, a plurality of conductive structures formed on the photodiodes for interconnections, and a passivation layer composed of silicon nitride or silicon oxide. The process for fabricating the CMOS image sensor and relative circuit structures is commonly known by those skilled in the art, thus are not discussed here.

After coating the photoresist on the wafer, an exposure process is performed on the wafer to transfer a particular pattern from the photomask to the photoresist, and a development process is performed thereafter. Preferably, the development process of the present invention involves a dynamic puddle process. First, a rotating apparatus is provided to perform a first rotating process on the wafer for generating a first rotating speed, in which the first rotating speed is between 400 rpm and 1000 rpm. While the wafer is rotating, a nozzle is utilized to evenly dispense a developer on the surface of the wafer. Next, a first static puddle process is performed to maintain the wafer in a static status for approximately 50 seconds. A second rotating process, such as a low speed rotating process, is performed thereafter to generate a second rotating speed for the wafer, in which the second rotating speed is less than the first rotating speed. Preferably, the second rotating speed is less than 300 rpm, and the second rotating process will generate a rotating puddle. Subsequently, a second static puddle process is performed after the second rotating process to maintain the wafer in a static status for approximately 10 seconds.

Next, a rinsing process is performed by utilizing a high pressure water column or conducting a pH change to rinse the wafer for ten seconds and remove the remaining developer from the surface of the wafer. Depending on the composition of the photoresist, the second rotating process, such as the rotating puddle step and the second static puddle process described previously can be performed repeatedly. According to the preferred embodiment of the present invention, the second rotating process and the second static puddle process are performed three times separately, but not limited thereto.

Preferably, the low speed rotating process and the second static puddle process may involve the following combinations: clockwise rotation, stop, and counterclockwise rotation. For example, the present invention is able to perform a clockwise rotating process on the wafer to generate a rotating puddle, and then stop the wafer for approximately ten seconds. Next, a second clockwise rotating process is performed on the wafer, and the wafer is stopped for another ten seconds thereafter. The two clockwise rotating processes can be performed repeatedly. Additionally, the present invention is able to first perform a clockwise rotating process on the wafer, and then stop the wafer for approximately ten seconds. Next, a counterclockwise rotating process is performed on the wafer, and the wafer is stopped for another ten seconds thereafter. The clockwise rotating process and the counterclockwise rotating process can be performed repeatedly. Subsequently, the dynamic puddle method can be applied to the developing process for fabricating color filters of different colors. After, structures such as barrier ribs and microlenses are formed on the color filters. The fabrication for a CMOS image sensor is now completed.

By first coating a developer on the surface of an exposed photoresist, performing a dynamic puddle treatment to the photoresist, such as the low speed rotating process described above, and performing a static puddle process by maintaining the wafer in a static status for approximately ten seconds, the present invention is able to effectively improve the red pigmentation problem caused by the high concentration property of the red photoresist material SR-3000L while fabricating a CMOS image sensor.

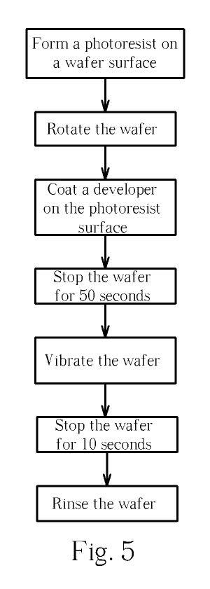

Please refer to FIG. 5. FIG. 5 is a flow chart diagram showing the process of fabricating a CMOS image sensor according to another embodiment of the present invention. As shown in FIG. 5, a semiconductor substrate is first provided, in which the semiconductor substrate is a silicon wafer, a silicon on insulator substrate, or a composite substrate composed of silicon, germanium, silicon germanium, or silicon carbide. Next, a spin-coating process is performed to form a photoresist on the surface of the semiconductor substrate, in which the photoresist is fabricated into a color filter in the later process. Preferably, the photoresist is selected from a pigment type photoresist commonly utilized in conventional fabrication processes, such as an RGB-3000L pigment type photoresist. Additionally, the surface of the wafer may include standard CMOS image sensor devices and relative circuit structures, such as a plurality of photodiodes utilized for collecting light, a plurality of conductive structures formed on the photodiodes for interconnections, and a passivation layer composed of silicon nitride or silicon oxide. The process for fabricating the CMOS image sensor and relative circuit structures is commonly known by those skilled in the art, thus are not discussed here.

After coating the photoresist on the wafer, an exposure process is performed on the wafer to transfer a particular pattern from the photomask to the photoresist, and a development process is performed thereafter. Preferably, the development process of the present invention involves a dynamic puddle process. First, a rotating apparatus is provided to perform a first rotating process on the wafer for generating a first rotating speed, in which the first rotating speed is between 400 rpm and 1000 rpm. While the wafer is rotating, a nozzle is utilized to evenly dispense a developer on the surface of the wafer. Next, a first static puddle process is performed to maintain the wafer in a static status for approximately 50 seconds.

Next, a vibrating process, such as a supersonic vibrating process is performed to vibrate the wafer. A second static puddle process is performed thereafter to maintain the wafer in a static status for ten seconds.

Next, a rinsing process is performed by utilizing a high pressure water column or conducting a pH change to rinse the wafer for ten seconds to remove the remaining developer from the surface of the wafer. Depending on the composition of the photoresist, the vibrating process and the second static puddle process described previously can be performed repeatedly. According to the preferred embodiment of the present invention, the vibrating process and the second static puddle process are performed three times separately, but not limited thereto. Additionally, the present invention is able to perform the rotating puddle process, described in the previous embodiment, simultaneously while performing the vibrating process, such as utilizing a supersonic wave to vibrate the wafer while rotating the wafer, thereby reducing the time required by the overall treatment process.

Preferably, the present invention first disposes an exposed photoresist on a wafer, coats a develop on the surface of the photoresist, performs a dynamic puddle process, such as a low speed rotating process or a vibrating process on the wafer, and stops the rotating wafer for approximately ten seconds. In other words, by utilizing a dynamic puddle developing process that involves performing a rotating puddle process and a static puddle process on the wafer, the present invention is able to improve the red pigmentation problem caused by the high pigment concentration of the red photoresist material SR-3000L while fabricating a CMOS image sensor, thereby improving the overall yield of the product. Additionally, the dynamic puddle developing process can be applied to any pattern transfer process utilized for fabricating optical devices, such as liquid crystal on silicon (LCOS) or other semiconductor processes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A dynamic puddle developing process, comprising:
(a) providing a semiconductor substrate having an exposed photoresist disposed thereon;
(b) coating a developer on the surface of the photoresist;
(c) performing a first static puddle process to maintain the semiconductor substrate in a static status within a first time interval;
(d) performing a rotating puddle process to generate a first rotating speed for the semiconductor substrate;
(e) performing a second static puddle process to maintain the semiconductor substrate in a static status within a second time interval; and
(f) performing a rinsing process to rinse the semiconductor substrate and remove the developer from the surface of the photoresist.

2. The dynamic puddle developing process of claim 1, wherein the semiconductor substrate comprises a wafer.

3. The dynamic puddle developing process of claim 1 further comprising performing a rotating process to generate a second rotating speed for the semiconductor substrate before coating the developer on the surface of the photoresist.

4. The dynamic puddle developing process of claim 3, wherein the second rotating speed is between 400 rpm and 1000 rpm.

5. The dynamic puddle developing process of claim 3, wherein the second rotating speed is faster than the first rotating speed.

6. The dynamic puddle developing process of claim 1, wherein the first time interval is less than 50 seconds.

7. The dynamic puddle developing process of claim 1, wherein the first rotating speed is slower than 300 rpm.

8. The dynamic puddle developing process of claim 1, wherein the second time interval is less than ten seconds.

9. The dynamic puddle developing process of claim 1, wherein the rinsing process is performed by utilizing a high presser water column.

10. The dynamic puddle developing process of claim 1, wherein the photoresist is utilized in a CMOS image sensor.

11. The dynamic puddle developing process of claim 10, wherein the photoresist is a color filter.

12. The dynamic puddle developing process of claim 1 further comprising repeating step (d) and step (e).

13. A dynamic puddle developing process, comprising:
(a) providing a semiconductor substrate having an exposed photoresist disposed thereon;
(b) coating a developer on the surface of the photoresist;
(c) performing a first static puddle process to maintain the semiconductor substrate in a static status within a first time interval;
(d) performing a vibrating process to vibrate the semiconductor substrate;
(e) performing a second static puddle process to maintain the semiconductor substrate in a static status within a second time interval; and
(f) performing a rinsing process to rinse the semiconductor substrate and remove the developer from the surface of the photoresist.

14. The dynamic puddle developing process of claim 13, wherein the semiconductor substrate comprises a wafer.

15. The dynamic puddle developing process of claim 13 further comprising performing a rotating process to generate a rotating speed for the semiconductor substrate before coating the developer on the surface of the photoresist.

16. The dynamic puddle developing process of claim 15, wherein the rotating speed is between 400 rpm and 1000 rpm.

17. The dynamic puddle developing process of claim 13, wherein the first time interval is less than 50 seconds.

18. The dynamic puddle developing process of claim 13, wherein the vibrating process comprises a supersonic vibrating process.

19. The dynamic puddle developing process of claim 13 further comprising performing a rotating puddle process.

20. The dynamic puddle developing process of claim 13, wherein the second time interval is less than ten seconds.

21. The dynamic puddle developing process of claim 13, wherein the rinsing process is performed by utilizing a high presser water column.

22. The dynamic puddle developing process of claim 13, wherein the photoresist is utilized in a CMOS image sensor.

23. The dynamic puddle developing process of claim 22, wherein the photoresist is a color filter.

24. The dynamic puddle developing process of claim 13 further comprising repeating step (d) and step (e).
